(19) United States
(12) Patent Application Publication
(10) Pub. No.: US 2006/0192245 A1
(43) Pub. Date: Aug. 31, 2006

(54) Semiconductor memory device and method for manufacturing the same

(76) Inventor: Keisuke Oosawa, Miyagi (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/314,368

(22) Filed: Dec. 22, 2005

(30) Foreign Application Priority Data
Feb. 28, 2005 (JP) 2005-052499

(51) Int. Cl. H01L 29/788

(52) U.S. Cl. 257/315

(57) ABSTRACT

When an insulating material deposited in a device isolation trench is etched, an etching process is performed to make a surface height of the insulating film lower than that of the device forming region. As a result, when a polysilicon film for a floating gate electrode is formed on a first tunnel film, the polysilicon film is curved downwardly on the insulating film (oxide film). Therefore, no peak shape is formed at ends of the floating gate electrode. By forming a floating gate electrode without the peak shape, the present invention can improve data retention characteristics of a semiconductor memory device.

### BACKGROUND OF THE INVENTION

1. Field of the Invention

The present invention relates to a semiconductor memory device having a floating gate electrode, a control gate electrode and a device isolation trench and a method for manufacturing the same. The present invention is applied to a semiconductor memory device such as an OTP-ROM (One Time Programmable-Read Only Memory) or an EEPROM (Electrically Erasable Programmable Read Only Memory).

2. Description of the Related Art

Semiconductor memory devices provided with a floating gate and a control gate electrode are known in the art. One example of such semiconductor memory devices is a non-volatile semiconductor memory device.

Also, device isolation is known in the art. For example, the device isolation is provided by a trench formed in a surface of a semiconductor substrate. The trench is filled with an isolation material. This device isolation is generally referred to as STI (Shallow Trench Isolation). The area of a device isolation region can be reduced by employing the STI structure, when compared to the LOCOS (Local Oxidation of Silicon). Thus, the degree of integration of semiconductor memory devices can be increased if the STI is used.

A structure of a conventional semiconductor memory device and a method for manufacturing the same will be described with reference to cross-sectional views shown in FIGS. 4A to 4G of the accompanying drawings.

(1) At first, a stopper film 402 and device isolation trenches 403 are formed on a surface of a semiconductor substrate 401. Next, an insulating material 404 is deposited over an entire surface of the semiconductor substrate 401. Thereafter, a surface of the semiconductor substrate 401 is polished using a CMP (Chemical Mechanical Polishing) method (see FIG. 4A).

(2) In the next step, the insulating material 404 deposited in the device isolation trench 403 is etched by a method such as wet etching with a fluorohydric acid, so that a filled oxide film 405 is prepared (see FIG. 4B). The surface height of the filled oxide film 405 is adjusted such that it is coplanar to or higher than that of a device forming region 406.

(3) Subsequently, the stopper film 402 is removed by wet etching or other method (see FIG. 4C).

(4) A first tunnel film 407 is formed on a surface of the device forming region 406 by a method such as oxidation diffusion or CVD (Chemical Vapor Deposition). The first tunnel film 407 is an insulation film. Then, a polysilicon film 408 for a floating gate electrode is formed on the first tunnel film 407 using a method such as LP-CVD (low-pressure chemical vapor deposition) (see FIG. 4D).

(5) The floating gate electrode 409 is created by patterning the polysilicon film 408 using a method such as photolithography or an etching technique (see FIG. 4E).

(6) Another insulating film (i.e., second tunnel film) 410 is formed on a top surface and side surfaces of the floating gate electrode 409, using a method such as oxidation diffusion or CVD. In addition, a polysilicon film 411 for a control gate is formed on the second tunnel film 410 using a method such as low pressure chemical vapor deposition (referring to FIG. 4F).

(7) A tungsten silicide film 412 is formed on the polysilicon film 411 to reduce a resistance. A stack of oxide and nitride films is prepared as an etching stopper film (not shown). Then, the films 411 and 412 are patterned using, for example, a conventional photolithography process or an etching process. After that, a control gate electrode 413 is completed by removing the etching stopper film (see FIG. 4G).

As described above, the surface of the oxide film 405 of the conventional semiconductor memory device is adjusted so as to be equal to or higher than the surface height of the device forming region 406 (see the above-described process (2) and FIG. 4B).

If the surface of the oxide film 405 is higher than the surface of the device forming region 406, and the polysilicon film 408 for the floating gate electrode is deposited on the oxide film 405, the polysilicon film 408 bends upwards on the buried oxide film 405 (see FIG. 4D). Therefore, if the floating gate electrode 409 is formed by etching the polysilicon film 408, both ends (formed on the oxide film 405) of the floating gate electrode 409 have an acute peak shape (hereinafter referred to as peak shape) (see a in FIG. 4E).

The peak shape portion causes the concentration of high electric field when a high voltage is applied to the floating gate electrode 409. The high voltage concentration deteriorates the charge retention properties of the floating gate electrode 409, which, will in turn, deteriorate the data retention properties of the semiconductor memory device.

In addition, the film thickness of the second tunnel film 410 becomes thin in the peak shape portion. As a result, the insulation of the floating gate electrode 409 and the control gate electrode 413 is affected, and therefore the data retention capability of the semiconductor memory device drops.

A technology to overcome these shortcomings is disclosed in, for example, a Japanese Patent No. 2637149. In this patent, a process for rounding the ends of the floating gate electrode 409 (that is, a process of removing the peak shape portion) is employed to eliminate the above-described shortcomings (see column 7, lines 37 to 41 in Japanese Patent No. 2637149 and FIG. 2C). In this patent, however, the number of manufacturing processes increases so that a new problem occurs in that the manufacturing cost of the semiconductor memory device increases.

If the surface height of the oxide film 405 is precisely aligned with that of the device forming region 406, the angle of the peak shape portion is increased (moderated) so that the above-described shortcomings are substantially overcome. Japanese Patent Application Kokai (Laid-Open) No. 11-163118 discloses a technology to align the height of the oxide film 405 with that of the device forming region 406. However, this also requires an additional manufacturing process, thereby increasing the manufacturing cost of the semiconductor memory device.

### SUMMARY OF THE INVENTION

It is one object of the present invention to provide, in an inexpensive way, a semiconductor memory device which does not have the peak shape at a floating gate electrode.

According to one aspect of the present invention, there is provided a semiconductor memory device that includes a substrate, a device isolation trench formed in a surface of the substrate, and an insulation film provided in the device isolation trench to create a device isolation region on the surface of the substrate. Two device forming regions are defined on both sides of the device isolation region on the substrate surface. A surface height of the insulation film is made lower than a surface height of the device forming region. The semiconductor memory device also includes a first tunnel film formed on each device forming region of the semiconductor substrate. The semiconductor device also includes a floating gate electrode formed on each first tunnel film. The floating gate electrode also extends on an end of the device isolation region. The semiconductor memory device also includes a second tunnel film formed on each floating gate electrode, and a control gate electrode formed on each second tunnel film.

A peak shape is not formed on the floating gate electrode since the insulating film surface is lower than the device forming region surface.

According to a second aspect of the present invention, there is provided an improved method for manufacturing a semiconductor memory device. The method includes forming a stopper film and a device isolation trench on a surface of a substrate. The method also includes forming an insulating film in the device isolation trench to create a device isolation region on the surface of the substrate, so that two device forming regions are defined on both sides of the device isolation region on the surface of the substrate. The method also includes polishing the surface of the substrate, and etching the insulating film until a surface height of the insulating film becomes below a surface height of the device forming region. The method also includes removing the stopper film, forming a first tunnel film on a surface of each said device forming region, and forming a floating gate electrode on each said first tunnel film such that the floating gate electrode also extends over an end of the device isolation region. The method also includes forming a second tunnel film on each said floating gate electrode, and forming a control gate electrode on each said second tunnel film.

By adjusting only an amount of etching in the etching step, the semiconductor memory device of the first aspect can be manufactured. Therefore, a semiconductor memory device without the peak shape on the floating gate electrode can be fabricated at low cost.

### BRIEF DESCRIPTION OF THE DRAWINGS

The above and other objects, aspects, features and advantages of the present invention will become apparent to those skilled in the art from the following detailed description and appended claims when read and understood in conjunction with the accompanying drawings, in which:

FIGS. 1A to 1G are a series of cross-sectional views showing a method of manufacturing a semiconductor memory device in accordance with one embodiment of the present invention;

FIGS. 2A, 2B and 2C are diagrams of an evaluation test carried out to the semiconductor memory device manufactured by the manufacturing method of FIGS. 1A to 1G;

FIGS. 3A and 3B are diagrams of evaluation results obtained from the test of FIGS. 2A to 2C; and

FIGS. 4A to 4G are a series of cross-sectional views showing a conventional method for manufacturing a semiconductor memory device.

### DETAILED DESCRIPTION OF THE INVENTION

Hereinafter, an embodiment of the present invention will be described in detail with reference to the accompanying drawings. It is to be understood that each of the elements in the drawings is schematically represented only to provide a better understanding of the present invention and the numerical conditions or the like mentioned in the following description are mere examples.

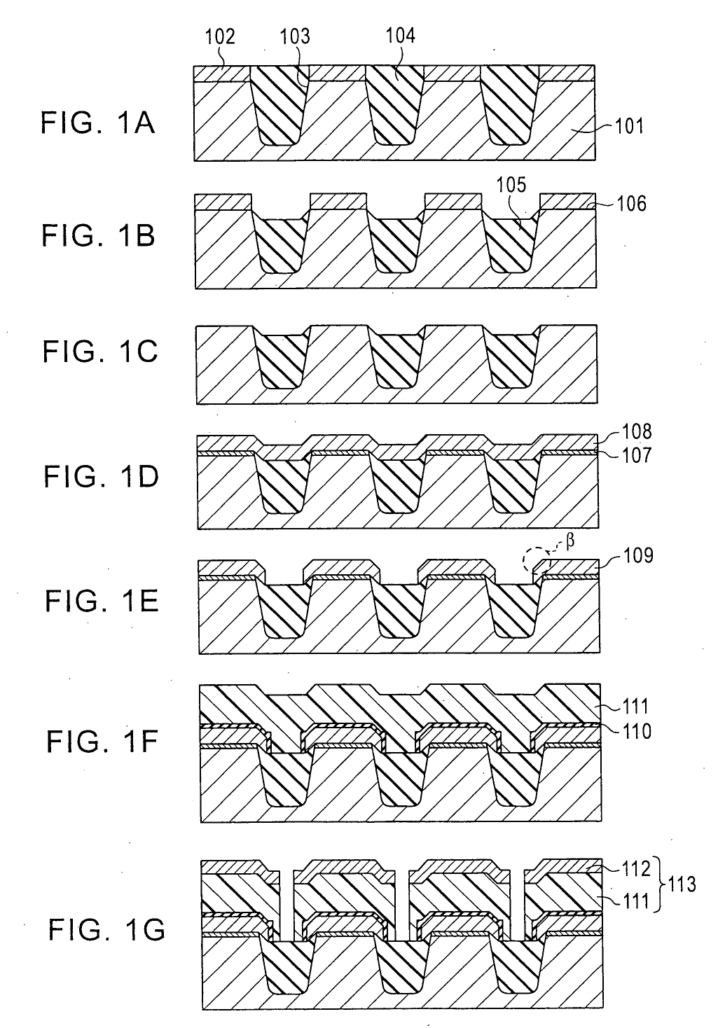

Referring to FIGS. 1A to 1G, each process of a method of manufacturing a semiconductor memory device in accordance with an embodiment of the present invention will be described.

(1) Similar to the conventional manufacturing process, firstly a stopper film 102 and device isolation trenches 103 are formed on a surface of a semiconductor substrate 101, and an insulating material 104 is formed over an entire surface of the semiconductor substrate 101. Then, the surface of the semiconductor substrate 101 is polished by CMP (Chemical Mechanical Polishing) (see FIG. 1A).

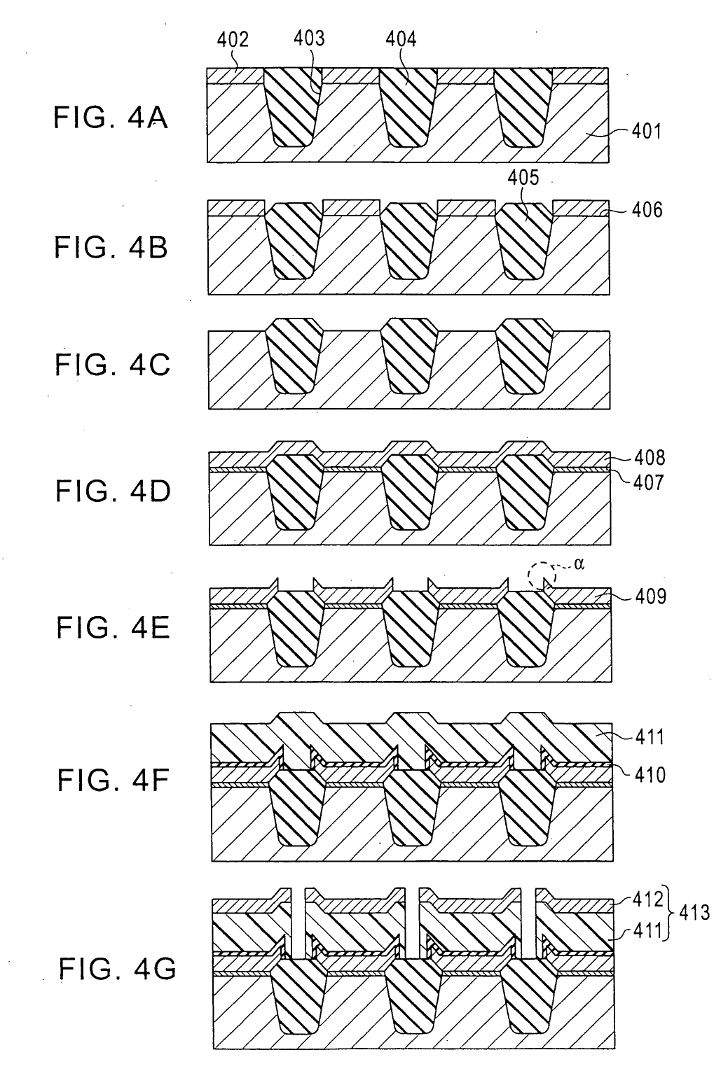

(2) In the next step, the insulating material 104 deposited on the device isolation trench 103 is etched by wet etching using fluorohydric acid, and an oxide film 105 is completed (see FIG. 1B). In this embodiment, unlike the conventional manufacturing process (see FIG. 4B), a surface height of the oxide film 105 is made lower than that of a device forming region 106.

(3) Subsequently, the stopper film 102 is removed by wet etching or the like (see FIG. 1C).

(4) Similar to the conventional manufacturing process, a first tunnel film 107 is formed on a surface of the device forming region 106 by an oxidation diffusion process or CVD process. A polysilicon film 108 for a floating gate electrode is formed on the first tunnel film 107 by low-pressure chemical vapor deposition (see FIG. 1D). As shown in FIG. 1D, in this embodiment, since the height of the surface of the filled oxide film 105 is lower than that of the device forming region 106, the polysilicon film 108 bends downwardly (or extends horizontally) above the oxide film 105.

(5) Similar to the conventional manufacturing process, a floating gate electrode 109 is formed by patterning the polysilicon film 108 using a method such as photolithography or etching (see FIG. 1E). As shown in FIG. 1E, the polysilicon film 108 is curved downwardly on the oxide film 105 in this embodiment, so that both ends of the floating gate electrode 109 (see β of FIG. 1E) do not have a peak shape.

(6) Similar to the conventional manufacturing process, an insulating film (i.e., second tunnel film) 110 is formed on a top surface and side surfaces of the floating gate electrode 109 using a method such as oxidation diffusion or CVD. A polysilicon film 111 for a control gate is formed on the second tunnel film 110 using a method such as a low-pressure chemical vapor deposition (see FIG. 1F). In this embodiment, there is no peak shape at the ends of the floating gate electrode 109 so that the thickness of the second tunnel film does not become thin at both ends of the floating gate electrode 109.

(7) Similar to the conventional manufacturing process, a tungsten silicide film 112 is formed over the polysilicon film 111, and a stack of oxide and nitride films is made as an etching stopper film. Then, the polysilicon film 111 is patterned by a conventional photolithography process or an etching process. Thereafter, a control gate electrode 113 is completed by removing the etching stopper film (see FIG. 1G).

As understood from the foregoing description, the floating gate electrode having no peak shape is obtained by simply adjusting an amount of etching in the above-described process (2). Therefore, this embodiment is capable of manufacturing a semiconductor memory device provided with a tunnel film having a uniform layer thickness.

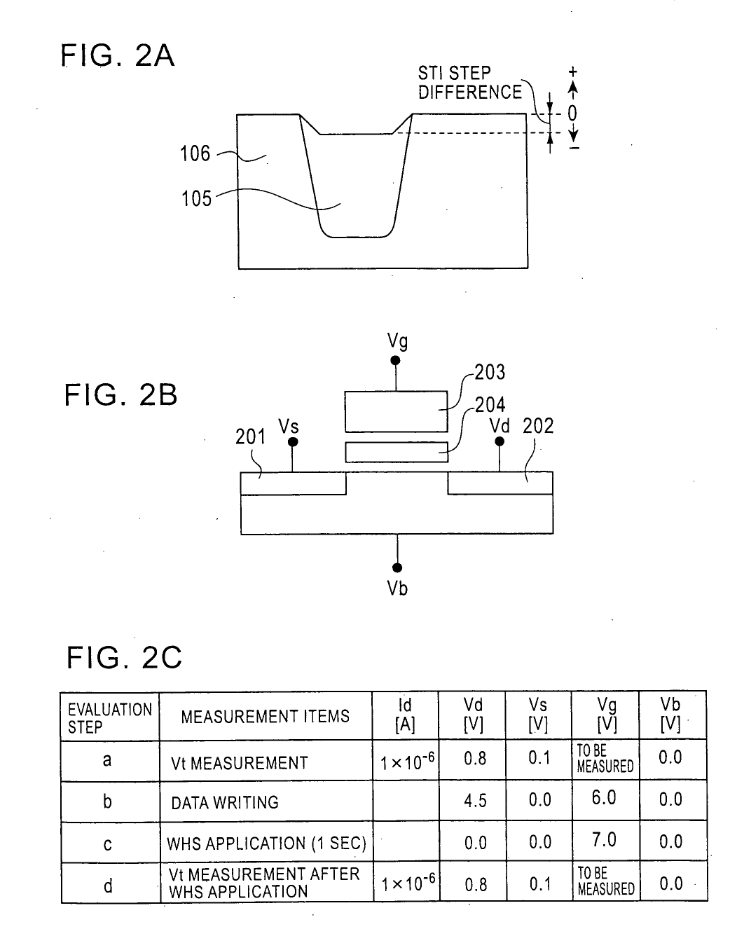

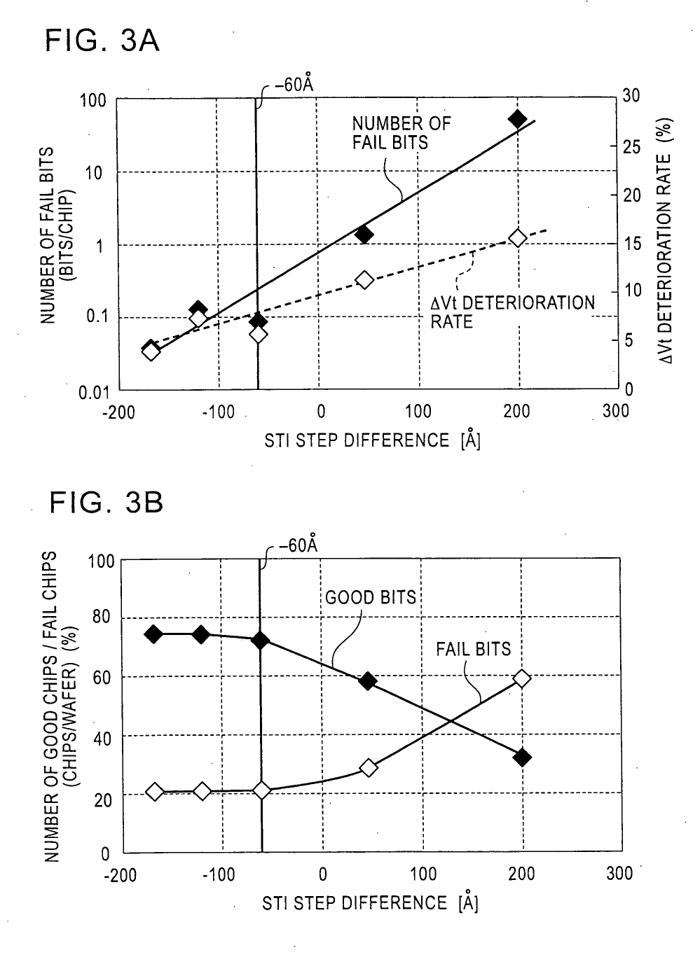

Next, evaluation test results of a semiconductor memory device manufactured by the above-described manufacturing processes will be described with reference to FIGS. 2A, 2B, 2C, 3A and 3B.

Firstly, the inventor of the present invention prepared six OTP-ROM test samples (cell gate length is 0.16 μm and capacity is 256 megabytes). The six test samples have different shapes. Specifically, the difference between the surface height of the oxide film 105 and the surface height of the device forming region 106 (referring to as an STI (Shallow Trench Isolation) step difference) is different. The six samples have 170 Å, 45 Å, −60 Å, −120 Å, −180 Å and −250 Å STI step differences, respectively. The value of the STI step difference (step height) is defined as a surface height of the oxide film 105 when the surface height of the device forming region 106 is considered 0, as shown in FIG. 2A. Therefore, the STI step difference has a positive value when the surface of the oxide film 105 is higher than that of the device forming region 106 and has a negative value when the surface of the oxide film 105 is lower than that of the device forming region 106. The first test sample has a 170 Å step difference and the second test sample has a 45 Å step difference, so that these test samples are manufactured according to the prior art (see FIGS. 4A to 4G). The third, fourth, fifth and sixth test samples, having −60 Å step difference, −120 Å step difference, −180 Å step difference and −250 Å step difference respectively, are manufactured according to the embodiment of the present invention (see FIGS. 1A to 1G).

Thereafter, the inventor performed a WHS (Word-Line High Stress) evaluation test using these test samples. The WHS evaluation test evaluates charge retention performance of a floating gate when a high voltage is applied to a control gate. The WHS evaluation test can reveal whether when data is written in an arbitrary OTP-ROM memory cell connected to a certain word line, another OTP-ROM memory cell connected to the same word line retains the written data as it is.

The detailed procedure of the WHS evaluation test will be explained with reference to FIGS. 2B and 2C.

(a) Firstly, for each test sample, the substrate voltage Vb is set to 0 volt, and then a drain current Id (=1×10⁻⁶ amperes) is passed between a source 201 and a drain 202 by appropriately adjusting a voltage Vs of the source 201 and a voltage Vd of the drain 202. At this time, a voltage Vg of a control gate electrode 203 is measured. The measurement result Vg is used as a threshold voltage Vt of the test sample concerned. Hereinafter, the control gate electrode voltage Vg obtained in this measurement is referred to as “Vt1”.

(b) In the next step, the substrate voltage Vb and the source voltage Vs are kept to 0 volt, the drain voltage Vd is kept to 4.5 volts, and the voltage Vg of the control gate electrode 203 is set to 6.0 volts so that data is written to each test sample. A charge is accumulated at the floating gate electrode 204 of each test sample upon the data writing.

(c) Subsequently, the substrate voltage Vb, the source voltage Vs and the drain voltage Vd are set to 0 volt. Then, 7.0 volts is applied to the control gate electrode 203. This voltage application corresponds to writing of data to another OTP-ROM connected to the same word line.

(d) The drain current Id between the source and drain is again set to 1×10⁻⁶ amperes. Then, the voltage Vg across the control gate electrode 203 is measured. Hereinafter, the control gate electrode voltage Vg obtained in this measurement is referred to as “Vt2”.

(e) Finally, a ΔVt deterioration rate a (=(Vt1−Vt2)/Vt1) is calculated from the voltage Vt1 obtained at the test step (a) and the voltage Vt2 obtained at the evaluation step (d). As the amount of the charges emitted from the floating gate 204 increases due to the high voltage application at the evaluation step (c), the amount of change Vt1−Vt2 in the threshold voltage increases, and therefore the Δ Vt deterioration rate σ also increases.

FIG. 3A is a graph representing a relation between the STI step difference and the ΔVt deterioration rate σ. In FIG. 3A, the horizontal axis represents the STI step difference of the WHS test samples, the left vertical axis represents the number of fail bits (the number of bits changed in the memory data value by the WHS test) per chip (256 megabytes), and the right vertical axis represents the average value of the ΔVt deterioration rate σ.

As shown in FIG. 3A, if the STI step difference is below −60 Å, the number of fail bits per chip is below 0.1 and the average value of the ΔVt deterioration rate σ is below 10%.

FIG. 3B is a graph representing a yield for the WHS test samples. The yield is calculated using a common product test process. In FIG. 3B, the horizontal axis represents the STI step difference of the WHS test samples and the vertical axis represents a ratio of the number of good chips to the number of defective chips per wafer. There are 290 chips on a single wafer.

As shown in FIG. 3B, if the STI step difference is below the −60 Å, yield is unchanged. On the other hand, if the STI step difference is above −60 Å, yield drops with the STI step difference.

As can be seen from the evaluation results, it is preferable that the STI step difference be below −60 Å.

Also, the inventor found that if the STI step difference is below −170 Å, etching residue (unetched polysilicon remaining on the semiconductor) increases in the etching process of the polysilicon film 108 (see the process (5) and FIG. 1E), and the etching process of the polysilicon film 111 (see the process (7) and FIG. 1G). Substantial etching residue remains on the oxide film 105, particularly on the oxide film 105 in a peripheral circuit region where the STI pattern is sparse, and in a CMP dishing region (a concave region formed during CMP). If the amount of etching is increased to reduce the generation of residue, the tunnel oxide films 107 and 110 are etched. In consideration of this, it is preferable that the STI step difference be above −170 Å.

As described above, this embodiment can eliminate the formation of the peak shapes at the floating gate of the semiconductor memory device without increasing the number of manufacturing processes. Therefore, it is possible to provide a semiconductor memory device with excellent data retention characteristics at low cost.

While the present invention has been described with respect to a particular embodiment, it will be apparent to those skilled in the art that various changes and modifications may be made without departing from the scope of the invention as defined in the appended claims.

This application is based on a Japanese Patent Application No. 2005-52499 filed on Feb. 28, 2005 and the entire disclosure thereof is incorporated herein by reference.

What is claimed is:

1. A semiconductor memory device comprising:
a substrate having a surface;
a device isolation trench in the surface of the substrate;
an insulating film provided in the device isolation trench to create a device isolation region on the surface of the substrate so that two device forming regions are defined on both sides of the device isolation region on the surface of the substrate, a surface height of the insulation film being lower than a surface height of each said device forming region;
a first tunnel film provided on each said device forming region of the substrate;
a floating gate electrode provided on each said first tunnel film such that the floating gate electrode also extends over an end of the device isolation region;
a second tunnel film formed on each said floating gate electrode; and
a control gate electrode formed on each said second tunnel film.

2. The semiconductor memory device as recited in claim 1, wherein a difference between the surface height of the insulating film and the surface height of the device forming region is greater than 60 Å.

3. The semiconductor memory device as recited in claim 1, wherein a difference between the surface height of the insulating film and the surface height of the device forming region is smaller than 170 Å.

4. The semiconductor memory device as recited in claim 2, wherein the difference between the surface height of the insulating film and the surface height of the device forming region is smaller than 170 Å.

5. The semiconductor memory device as recited in claim 1, wherein the semiconductor memory device is an OTP-ROM or EEPROM.

6. A method for manufacturing a semiconductor memory device, comprising:
forming a stopper film and a device isolation trench on a surface of a substrate;
forming an insulating film in the device isolation trench to create a device isolation region in the surface of the substrate, so that two device forming regions are defined on both sides of the device isolation region on the surface of the substrate;
polishing the surface of the substrate;
etching the insulating film until a surface height of the insulating film is below a surface height of the device forming region;
removing the stopper film;
forming a first tunnel film on each said device forming region;
forming a floating gate electrode on each said first tunnel film such that the floating gate electrode also extends over an end of the device isolation region;
forming a second tunnel film on each said floating gate electrode; and
forming a control gate electrode on each said second tunnel film.

7. The method as recited in claim 6, wherein the etching is performed such that a difference between the surface height of the insulating film and the surface height of the device forming region becomes greater than 60 Å.

8. The method as recited in claim 6, wherein the etching is performed such that a difference between the surface height of the insulating film and the surface height of the device forming region is less than 170 Å.

9. The method as recited in claim 7, wherein the etching is performed such that the difference between the surface height of the insulating film and the surface height of the device forming region is less than 170 Å.

10. The method as recited in claim 6, wherein the polishing is chemical mechanical polishing.

11. The method as recited in claim 6, wherein the etching is wet etching with fluorohydric acid.

12. The method as recited in claim 6, wherein the removing the stopper film is performed by wet etching.

13. The method as recited in claim 6, wherein the forming the first tunnel film is performed by oxidation diffusion process or CVD.

14. The method as recited in claim 6, wherein the forming the floating gate electrode includes low-pressure CVD.

15. The method as recited in claim 6, wherein the forming the second tunnel film is performed by oxidation diffusion process or CVD.

16. The method as recited in claim 6, wherein the forming the control gate electrode includes low-pressure CVD.

17. The method as recited in claim 6, wherein the semiconductor memory device is an OTP-ROM or EEPROM.
